(19) United States
(12) Patent Application Publication
(10) Pub. No.: US 2020/0013588 A1
(43) Pub. Date: Jan. 9, 2020

(54) TILTED INTERFEROMETRIC ENDPOINT (IEP) WINDOW FOR SENSITIVITY IMPROVEMENT

(71) Applicant: Applied Materials, Inc., Santa Clara, CA (US)

(72) Inventors: Lei LIAN, Fremont, CA (US); Pengyu HAN, Santa Clara, CA (US)

(21) Appl. No.: 16/026,486

(22) Filed: Jul. 3, 2018

(51) Int. Cl. H01J 37/32; H01L 21/67; H01L 21/3065; H01L 21/66

(52) U.S. Cl. CPC H01J 37/32458; H01L 21/67069; H01L 21/67253; H01J 37/32715; H01L 22/26; H01J 37/32963; H01L 21/3065

(57) ABSTRACT

A tilted window for use in an endpoint detection system of a processing chamber, and a processing chamber having the same are described herein. In one example, the tilted window includes a mounting frame, and a panel mounted in the mounting frame. The mounting frame has a body having a top surface, a bottom surface, and an inner edge connecting the top surface to the bottom surface of the body of the mounting frame. The mounting frame further has a panel disposed in the mounting frame. The panel has a body having a top surface and a bottom surface. The top surface of the body of the panel is oriented at acute angle relative to the top surface of the body of the mounting frame.

### BACKGROUND

### Field

Embodiments of the present disclosure generally relate to etching semiconductor substrates, and more particularly, to a transparent chamber window for use in an endpoint detection system having reduced reflections of incident and reflected light.

### Description of the Related Art

Semiconductor device geometries have dramatically decreased in size since such devices were first introduced several decades ago. The increasing circuit densities have placed additional demands on processes used to fabricate semi-conductor devices. For example, as circuit densities increase, the widths of vias, contacts and other features, as well as the dielectric materials between them, decrease to sub-micron dimensions, whereas the thickness of the dielectric layers remains substantially constant, with the result that the aspect ratios for the features, i.e., their height divided by width, increases. Reliable formation of high aspect ratio features is important to the success of sub-micron technology and to the continued effort to increase circuit density and quality of individual substrates.

High aspect ratio features are conventionally formed by patterning a surface of a substrate to define the dimensions of the features and then etching the substrate to remove material and define the features. To form high aspect ratio features with a desired ratio of height to width, the dimensions of the features must be formed within certain parameters, which are typically defined as the critical dimensions of the features. Consequently, reliable formation of high aspect ratio features with desired critical dimensions requires precise patterning and subsequent etching of the substrate.

In integrated circuit manufacturing, it is necessary to structure layers to form the high aspect ratio features. Accordingly, it may be necessary to partially remove one or more layers using a dry etching or plasma etching process. During plasma etching, a mask is utilized to transfer a pattern to a target layer disposed on a substrate without etching a layer disposed underlying the target layer. To prevent etching the underlying layer, endpoint techniques such as interferometry are utilized. Interferometry uses polarization and interference of reflected light to recognize the change of the optical properties of a surface, which can be used to indicate when the target layer is removed completely and the light is suddenly reflected from a different material surface of the underlying layer.

An interferometer measures the difference of two or more light paths by overlapping the residual light from both paths, generating interference fringes. A monochromatic light source is used and reflected from the surface of the target layer. The reflected light is overlapped with a reference light beam. Small changes in the range of the light source wavelength can be recognized.

The reflected light is a combination of signals from each layer disposed on the substrate and special interference fringes are formed for each layer. For end point detection, the interference fringe pattern can be simulated for various layers and then compared during etching with the measured signal. The method is very effective and can be used for monitor etching and end point detection of substrates with two or more layers.

Transmitted and reflected light generally passes through a generally flat, transparent window in a plasma etch chamber with incidence view of the substrate being etched. Unfortunately, conventional flat interferometry endpoint (IEP) detection windows encounter significant internal reflection and reduced sensitivity to on-substrate metrics while etching. A typical approach to reducing internal reflections in the IEP window is to employ anti-reflective coatings (ARC) at surfaces of the window. Unfortunately, ARCs only work over a limited range of wavelengths when it is necessary to remove internal reflections over a range of wavelengths, generally from 200 nm to 800 nm.

Therefore, a need exists in the art for an improved window for an endpoint detection system.

### SUMMARY

Embodiments presented herein provide a tilted window for use an endpoint detection system of a processing chamber. The tilted window includes a mounting frame, and a panel mounted in the mounting frame. The mounting has a body having a top surface, a bottom surface, and an inner edge connecting the top surface to the bottom surface of the body of the mounting frame. The mounting frame further has a panel disposed in the mounting frame. The panel has a body having a top surface and a bottom surface. The top surface of the body of the panel is oriented at acute angle relative to the top surface of the body of the mounting frame.

Embodiments presented herein further provide a processing chamber. The processing chamber includes a chamber body, a ceiling mounted overlying the chamber body, and a chamber bottom mounted underlying the chamber body, wherein the chamber body, the ceiling, and the chamber bottom define an inner space of the chamber. The processing chamber further includes an inductive coil disposed around at least a portion of the ceiling. The processing chamber further includes a substrate support member disposed in the inner space of the processing chamber. The substrate support member includes a support surface on which a substrate is held during processing. The processing chamber further includes an endpoint detection system optically coupled to a tilted window mounted in the ceiling. The tilted window includes a surface through which an endpoint signal is directed. The surface of the tilted window disposed at an acute angle relative to the support surface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic cross sectional view of a plasma etch chamber in accordance with one embodiment of the present disclosure.

FIG. 2 is a side view of a tilted window employed in an endpoint detection system of the processing chamber, in accordance with embodiments of the present disclosure.

FIG. 3 is a top view of the tilted window of FIG. 2.

FIG. 4 is a sectional view of the tilted window taken through section line 4-4 of FIG. 3.

FIG. 5A is a plot of reflection magnitude versus wavelength for a conventional window.

FIG. 5B is a comparison between a plot of reflection magnitude versus wavelength for a conventional window and that of a tilted window.

FIG. 6 depicts a plot of magnitude of normalized amplitude versus etch recess depth for the tilted window.

FIG. 7A depicts plots of magnitude versus relative time of fringe curve spectra from the angled window versus a conventional window.

FIG. 7B depicts plots of magnitude versus wavelength of fringe curve spectra from the angled window versus a conventional window.

To facilitate understanding, identical reference numerals have been used, wherever possible, to designate identical elements that are common to the Figures. Additionally, it is contemplated that elements disclosed in one embodiment may be beneficially used in other embodiments described herein without specific recitation.

### DETAILED DESCRIPTION

The titled window presented herein can effectively reduce internal reflections over a wide range of wavelengths of interest, such as between about 200 to 800 nm, without the need of anti-reflection coatings. The dynamic range of the IEP system is improved. The direct benefits of the tilted window are improved etch depth control accuracy and extended window life time. The tilted window is generally compatible with existing chamber bodies, and as such, may be retrofit into almost all existing chambers that utilize IEP systems.

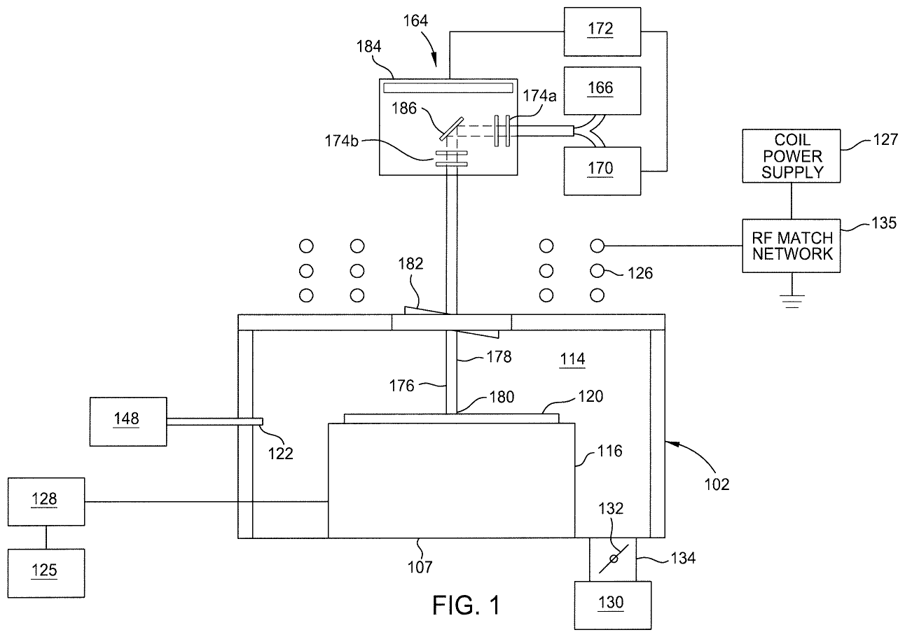

FIG. 1 is a schematic cross sectional view of a plasma processing chamber 100 in accordance with one embodiment of the present disclosure. Suitable processing chambers include inductively coupled plasma etch chambers such as the TETRA® photomask etch system and the AdvantEdge® etch system, both available from Applied Materials, Inc., of Santa Clara, Calif., among others. Other types of processing chambers may be adapted to benefit from the invention, including, for example, capacitive coupled parallel plate chambers and magnetically enhanced ion etch chambers, as well as inductively coupled plasma etch chambers of different designs.

The processing chamber 100 generally includes a chamber body 102 and an energy transparent ceiling 103. The chamber body 102 also has a chamber bottom 107. The chamber body 102 is fabricated from a metal, such as anodized aluminum or stainless steel. The ceiling 103 mounted on the body 102. The ceiling 103 may be flat, rectangular, arcuate, conical, dome or multi-radius shaped. The ceiling 103 is fabricated from an energy transparent material such as a ceramic or other dielectric material. An inductive coil 126 is disposed over the ceiling 103 of the processing chamber 100, and is utilized to energize gases within the chamber 100 during processing.

A substrate support member 116 is disposed in the processing chamber 100 to support a substrate 120 during processing. The support member 116 may include an electrostatic chuck, with at least a portion of the support member 116 being electrically conductive and capable of serving as a process bias cathode.

Processing gases are introduced into the processing chamber 100 from a process gas source 148 through a gas distributor 122. The gas distributor 122 may be disposed in the ceiling 103 or chamber body 102, generally above the support member 116. Mass flow controllers (not shown) for each processing gas, or alternatively, for mixtures of the processing gas, are disposed between the gas distributor 122 and the process gas source 148 to regulate the respective flow rates of the process gases into the chamber body 102.

A plasma zone 114 is defined in the chamber body 102 between the substrate support member 116 and the ceiling 103. A plasma is formed in the plasma zone 114 from the processing gases using a coil power supply 127 which supplies power to the inductive coil 126 to generate an electromagnetic field in the plasma zone 114 through an RF match network 135. The support member 116 may include an electrode disposed therein, which is powered by an electrode power supply 128 and generates a capacitive electric field in the processing chamber 100 through an RF match network 125. Typically, RF power is applied to the electrode in the support member 116 while the body 102 is electrically grounded. The capacitive electric field is transverse to the plane of the support member 116, and influences the directionality of charged species more normal to the substrate 120 to provide more vertically oriented anisotropic etching of the substrate 120.

Process gases and etchant byproducts are exhausted from the processing chamber 100 through an exhaust system 130. The exhaust system 130 may be disposed in the bottom 107 of the processing chamber 100 or may be disposed in another portion of the body 102 of the processing chamber 100 for removal of processing gases. A throttle valve 132 is provided in an exhaust port 134 for controlling the pressure in the processing chamber 100.

FIG. 1 further illustrates an endpoint detection system 164 connected to the processing chamber 100 in accordance with one embodiment of the invention. The endpoint detection system 164 may be an interferometer endpoint (IEP) detection system. The endpoint detection system 164 is positioned to interface with the substrate through a portion of the ceiling 103. In one example, the detection system 164 is positioned to interface a peripheral portion of the substrate through a portion of the ceiling 103 that is offset from the center of the ceiling 103. In this manner, the endpoint detection system 164 has a direct line of sight to detect a peripheral region surface of the substrate 120.

The endpoint detection system 164 generally comprises a light source 166, a focusing assembly 168, and a light detector 170. The light source 166 is configured to emit a light beam. The focusing assembly 168 is configured to focus the light beam into an incident light beam 176. The incident light beam 176 passes through the ceiling 103 and illuminate an area or spot 180 on the surface of the substrate 120. The incident light beam 176 is reflected by the surface of the substrate 120 to form a reflected light beam 178. At least a portion of the reflected light beam 178 is directed back through ceiling 103 to the light detector 170. The light detector 170 is configured to measure the intensity of the reflected light beam 178. A computer system 172 calculates portions of the real-time measured waveform spectra of light beam 178 reflected from the beam spot 180 on substrate 120 and compares the spectra with a stored characteristic waveform pattern.

The light source 166 comprises a monochromatic or polychromatic light source that generates the incident light beam 176 used to illuminate the beam spot 180 on substrate 120. The intensity of the incident light beam 176 is selected to be sufficiently high enough to enable the reflected light beam 178 to have a measurable intensity. In one version, the light source 166, such as an Hg—Cd lamp, provides a polychromatic light and generates an emission spectrum of light in wavelengths from about 200 nm to about 600 nm. The polychromatic light source 166 can be filtered to select the frequencies comprising the incident light beam 176. Color filters can be placed in front of the light detector 170 to filter out all wavelengths except for the desired wavelength(s) of light, prior to measuring the intensity of the reflected light beam 178 entering the light detector 170. The light source 166 can also comprise a flash lamp or a monochromatic light source, for example an He—Ne or ND-YAG laser, that provides a selected wavelength of light.

One or more focusing lenses 174a, 174b may be used to focus the incident light beam 716 from the light source 166 to form the beam spot 180 on the substrate surface, and to focus the reflected light beam 178 back on the active surface of light detector 170. The size or area of the beam spot 180 should be sufficiently large to compensate for variations in surface topography of the substrate 120 and device design features. This enables detection of etch endpoints for high aspect ratio features having small openings, such as vias or deep narrow trenches, which may be densely present or more isolated. The area of the reflected light beam should be sufficiently large to activate a large portion of the active light-detecting surface of the light detector 170.

The incident and reflected light beams 176, 178 are directed through a transparent tilted window 182 of the processing chamber 100. The tilted window 182 allows the light beams to pass in and out of the processing environment of the processing chamber 100 substantially without producing internal reflections.

The diameter of the beam spot 180 is generally about 2 mm to about 10 mm. However, if the beam spot 180 encompasses large isolated areas of the substrate containing only a small number of etched features, it may be necessary to use a larger beam spot in order to encompass a greater number of etched features. The size of the beam spot can therefore be optimized, depending on the design features for a particular device.

Optionally, a light beam positioner 184 may be used to move the incident light beam 176 across the substrate 120 to locate a suitable portion of the substrate surface on which to position the beam spot 180 to monitor an etching process. The light beam positioner 184 may include one or more primary mirrors 186 that rotate at small angles to deflect the light beam from the light source 166 onto different positions of the substrate surface. Additional secondary mirrors may be used (not shown) to intercept the reflected light beam 178 that is reflected from the substrate 120 surface and focus the reflected light beam 178 on the light detector 170. The light beam positioner 184 may also be used to scan the light beam in a raster pattern across the substrate 120 surface. In this version, the light beam positioner 184 comprises a scanning assembly consisting of a movable stage (not shown), upon which the light source 166, the focusing assembly 168 and the detector 170 are mounted. The movable stage can be moved through set intervals by a drive mechanism, such as a stepper motor, to move the beam spot 180 across the substrate 120 surface.

The light detector 170 comprises a light-sensitive electronic component, such as a photovoltaic cell, photodiode, or phototransistor, which provides a signal in response to a measured intensity of the reflected light beam 178 that is reflected from the substrate 120 surface. The signal can be in the form of a change in the level of a current passing through an electrical component or a change in a voltage applied across an electrical component. The reflected light beam 178 undergoes constructive and/or destructive interference which increases or decreases the intensity of the light beam, and the light detector 170 provides an electrical output signal in relation to the measured intensity of the reflected light beam 178. The electrical output signal is plotted as a function of time to provide waveform spectra having numerous waveform patterns corresponding to the varying intensity of the reflected light beam 178.

A computer program on the computer system 172 compares the shape of the measured waveform pattern of the reflected light beam 178 to a stored characteristic waveform pattern and determines the endpoint of the etching process when the measured waveform pattern is the same as the characteristic waveform pattern. As such, the period of interference signal may be used to calculate the depth and etch rate. The program may also operate on the measured waveform to detect a characteristic waveform, such as, an inflection point. The operations can be simple mathematic operations, such as evaluating a moving derivative to detect an inflection point.

Although the endpoint detection system 164 is positioned to interface with the substrate through a portion of the substantially horizontal ceiling 103 of the processing chamber 100, the endpoint detection system 164 can, in some embodiments, be located horizontally above the chamber 100 and further include a folding mirror above the chamber 100 to bend the incident light beam 176 and the reflected light beam 178 from a vertical position to the horizontal position. The transparent tilted window 182 may be placed on a side of the chamber 100 or a bottom of the chamber 100.

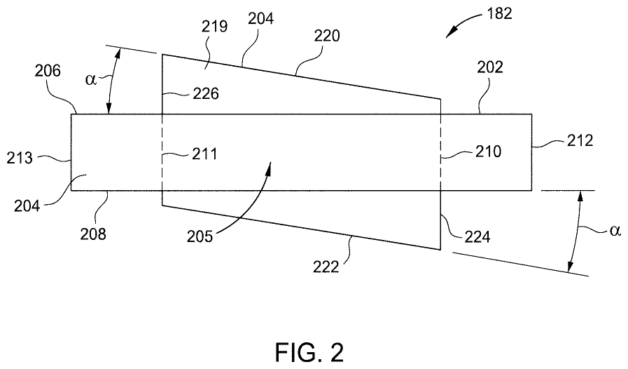

FIG. 2 is a side view of the tilted window 182 employed in the endpoint detection system 164 of the processing chamber 100. The tilted window 182 includes a mounting frame 202 and a panel 204 disposed in the mounting frame 202. The mounting frame 202 has a body 205 having a top surface 206 and a bottom surface 208. In one embodiment, the top surface 206 is parallel to the bottom surface 208. The mounting frame 202 also includes a near inner edge 210 and a near outer edge 212. In one embodiment, the near inner edge 210 is parallel to the near outer edge 212 and perpendicular to the top surface 206 and the bottom surface 208. The mounting frame 202 also includes a far inner edge 211 and a far outer edge 213. In one embodiment, the far outer edge 211 is parallel to the far outer edge 213 and perpendicular to the top surface 206 and the bottom surface 208.

The panel 204 has a body 219 having a top surface 220 and a bottom surface 222. In one embodiment, the top surface 220 is parallel to the bottom surface 222. The panel 204 also includes a near outer edge 224 and a far outer edge 226. In one embodiment, the near outer edge 224 and the far outer edge 226 are oriented at an angle relative to the top surface 220 and the bottom surface 222. In one embodiment, the angle of the top surface 220 of the panel relative to the top surface 206 of the mounting frame 202 is an acute angle α. In one embodiment, the acute angle α is about five (5) degrees or less. In another embodiment, the acute angle α is about five (3) degrees.

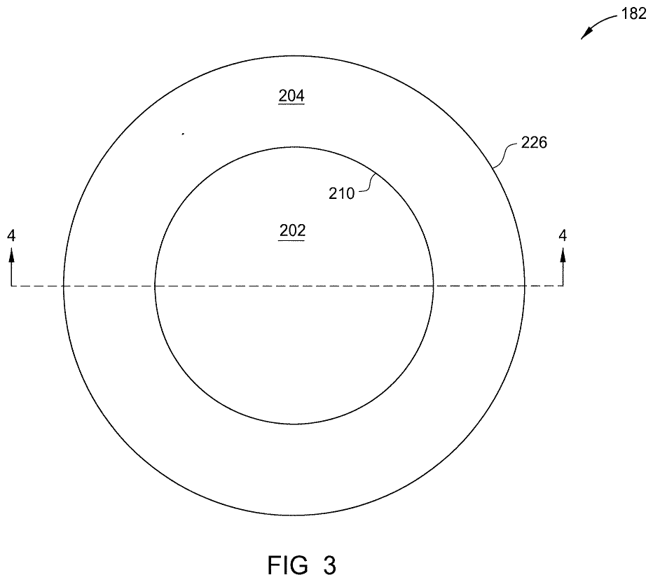

FIG. 3 is a top down view of the tilted window 182. In one embodiment, the panel 204 is substantially circular and forms a disk internal to the mounting frame 202. In other embodiments, the panel 204 may be substantially square, rectangular, triangular, or elliptical in shape, etc. In one embodiment, the panel 204 may be made of sapphire. It is contemplated that other transparent materials may be used.

In one embodiment, the mounting frame 202 is substantially circular and forms an annular ring about the panel 204. In other embodiments, the mounting frame 202 may be substantially square, rectangular, triangular, or elliptical in shape, etc. In one embodiment, the mounting frame 202 may be made of sapphire, fused silica, or MgF₂. It is contemplated that other transparent or non-transparent materials may be used. The material of the mounting frame 202 may be different from the material of the panel 204, but a one piece design promotes maintaining a vacuum seal between the mounting frame 202 and the panel 204.

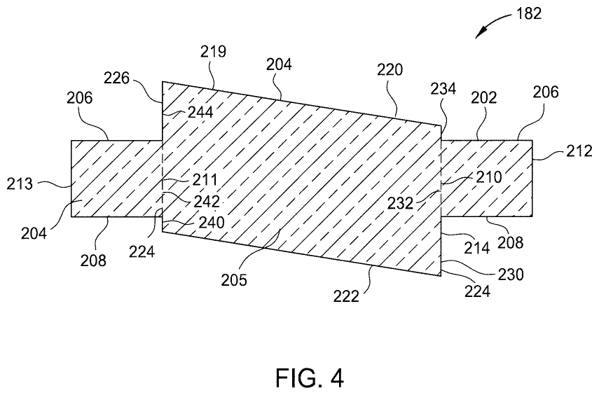

FIG. 4 is a cut-away side view of the tilted window 182 taken through along the line 4-4 of FIG. 3. The near outer edge 224 of the panel 204 has a first portion 230, a central portion 232 disposed above the first portion 230, and a third portion 234 extending above the central portion 232. The first portion 230 extends below the bottom surface 208 of the mounting frame 202. The third portion 234 extends above the top surface 206 of the mounting frame 202. The central portion 232 at least partially adjoins the near inner edge 210 of the mounting frame 202. The central portion 232 adjoins the near inner edge 210 of the mounting frame 202 such that to the top surface 220 of the panel 204 is oriented at an acute angle α relative to the top surface 206 of the mounting frame 202. In one embodiment, the acute angle α is less than about five (5) degrees. In another embodiment, the acute angle α is about three (3) degrees.

The far outer edge 226 of the panel 204 has a first portion 240, a central portion 242 disposed above the first portion 240, and a third portion 244 extending above the central portion 242. The first portion 240 extends below the bottom surface 208 of the mounting frame 202, but has a length that is shorter than the first portion 230 of the near outer edge 224 and a length that is about equal to a length of the third portion 234 of the near outer edge 224. The third portion 244 extends above the top surface 206 of the mounting frame 202, but has a length that is longer than the third portion 234 of the near outer edge 224 and a length that is about equal to a length of the first portion 230 of the near outer edge 224. The central portion 242 at least partially adjoins the far inner edge 211 of the mounting frame 202. The central portion 242 of the far inner edge 211 has a length that is about equal to the central portion 232 of the near outer edge 224. The central portion 242 adjoins the far outer edge 226 of the mounting frame 202 such that the bottom surface 222 of the panel 204 is oriented at an acute angle α relative to the top bottom 206 of the mounting frame 202. In one embodiment, the acute angle α is less than about five (5) degrees. In another embodiment, the acute angle α is about three (3) degrees.

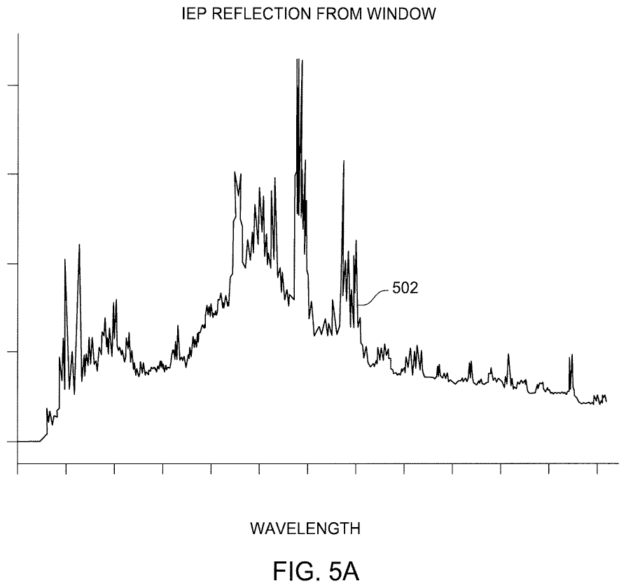

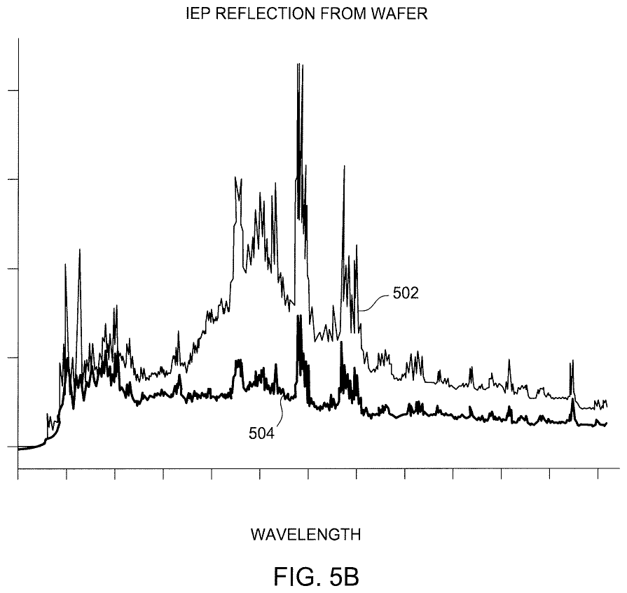

FIG. 5A depicts a plot of magnitude of reflections versus wavelength for a conventional window. FIG. 5B compares a plot of magnitude of reflections versus wavelength for a conventional window compared to the tilted window 182. The plot 502 is an indication of the magnitude of reflections from a conventional window and the plot 504 is an indication of the magnitude of reflections from the tilted window 182. There are almost no reflections from the angled window as compared to about 20K counts (counts is a unit of spectrometer output) for a conventional window. IEP spectra from a wafer with the angled window is composed of spectra reflected from the substrate only, without the 20 k counts background reflections are from the conventional IEP window. The IEP tilted window 182 improves IEP modulation significantly.

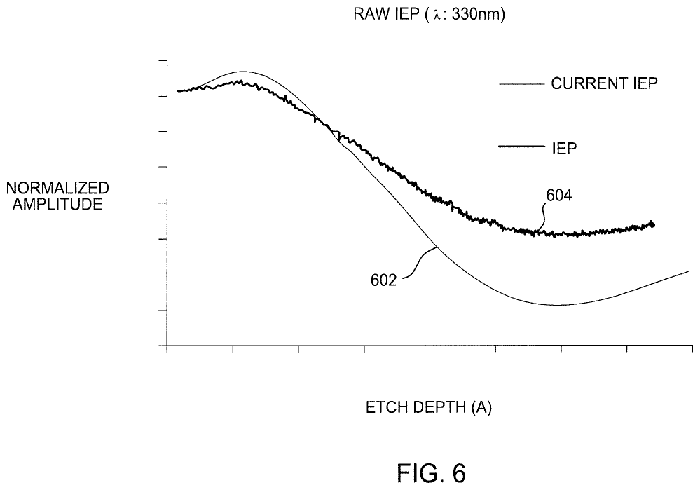

FIG. 6 depicts plots of magnitude of normalized amplitude versus etch recess depth for the tilted window (plot 602) and the conventional window (plot 604). The range of recess depth controlled by using an etch IEP algorithm with the angled window can be reduced by ˜10 Å based on lab test results on WEB (WEB stand for W (tungsten) etch back) chips. 15 Å˜20 Å variations in etch depth can be achieved using the angled window.

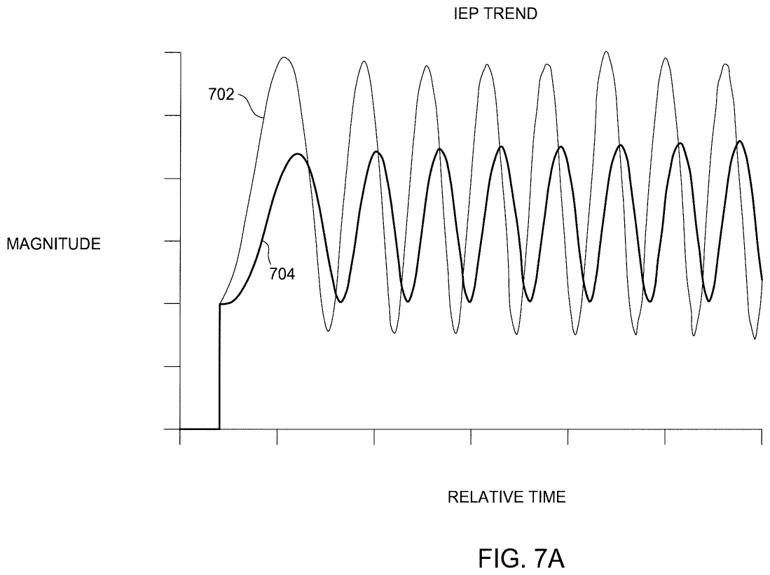

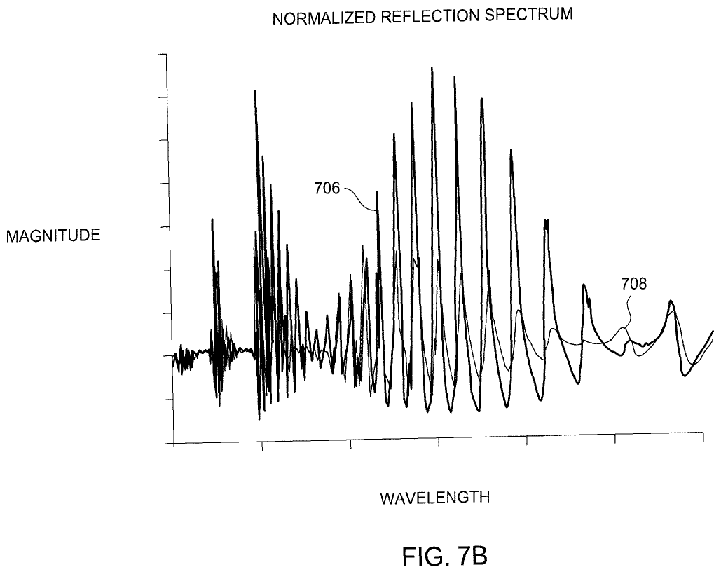

FIG. 7A depicts plots of magnitude versus relative time of fringe curve spectra from the angled window (plot 702) versus a conventional window (plot 704). FIG. 7B depicts plots of magnitude versus wavelength of fringe curve spectra from the angled window plot 706 versus a conventional window plot 708. As can be seen from the plots, IEP modulation depth (sensitivity) is increased by about 80% for the conventional window plots 704, 706 versus the angled window plots 704, 708. This is desired because spectral analysis is relied on to calculate the on wafer metric (dimension of features at the wafer surface) and the stronger the spectral response to subtle on wafer metric change, the higher the signal to noise ratio is and more accurate results are obtained of the on wafer metric.

While the foregoing is directed to embodiments of the present disclosure, other and further embodiments of the disclosure may be devised without departing from the basic scope thereof, and the scope thereof is determined by the claims that follow.

What is claimed is:

1. A tilted window suitable for use in an endpoint detection system of a processing chamber, the tilted window comprising:
a mounting frame having a body having a top surface, a bottom surface, and an inner edge connecting the top surface to the bottom surface of the body of the mounting frame; and
a panel disposed in the mounting frame, the panel having a body having a top surface and a bottom surface, the top surface of the body of the panel oriented at acute angle relative to the top surface of the body of the mounting frame.

2. The tilted window of claim 1, wherein the acute angle is less than about five degrees.

3. The tilted window of claim 1, wherein the panel is substantially transparent.

4. The tilted window of claim 1, wherein the panel is made of sapphire.

5. The tilted window of claim 1, wherein the panel is substantially circular in shape.

6. The tilted window of claim 1, wherein the top surface of the mounting frame is substantially parallel to the bottom surface of the mounting frame.

7. The tilted window of claim 1, wherein the top surface of the panel is substantially parallel to the bottom surface of the panel.

8. The tilted window of claim 1, wherein the mounting frame is made of one of sapphire, fused silica, or MgF₂.

9. The tilted window of claim 1, wherein the mounting frame further has a near outer edge connecting the top surface to the bottom surface of body of the panel, the near outer edge having a first portion, a central portion disposed above the first portion, and a third portion extending above the central portion, the central portion at least partially adjoining the inner edge of the body mounting frame.

10. A tilted window suitable for use in an endpoint detection system of a processing chamber, the tilted window comprising:
a mounting frame having a body having a top surface and a bottom surface, the top surface substantially parallel to the bottom surface, the mounting frame further including an inner edge and an outer edge, the inner edge being parallel to the outer edge and perpendicular to the top surface,
a transparent panel mounted in and surrounded by the mounting frame, the panel having a body that includes a top surface and a bottom surface parallel to the top surface of the panel, the panel further including a near outer edge and a far outer edge, wherein the near outer edge and the far outer edge form a first acute angle relative to the top surface and the bottom surface of the panel, the panel forming a disk internal to the mounting frame and made of sapphire, wherein the near outer edge of the panel has a first portion, a central portion disposed above the first portion, and a third portion extending above the central portion, the first portion extending underlying the inner edge of the mounting frame, the third portion extending overlying the inner edge of the mounting frame, the central portion at least partially adjoining the inner edge of the mounting frame such that the top surface and the bottom surface of the panel is oriented at a second acute angle relative to the top surface and the bottom surface of the mounting frame, the far outer edge extending partially extends above the top surface of the mounting frame.

11. The tilted window of claim 10, wherein the first acute angle and the second acute angle are about five degrees.

12. A processing chamber, comprising:
a chamber body having sidewalls and a bottom;
a ceiling mounted overlying the chamber body, the ceiling and the chamber body defining an inner space of the processing chamber;
a substrate support member disposed in the inner space of the processing chamber and configured to support a substrate during processing;
an endpoint detection system; and
a tilted window mounted in the ceiling and configured to allow the endpoint detection system to interface with the substrate through the tilted window, the tilted window comprising:
a mounting frame having a body having a top surface, a bottom surface, and an inner edge connecting the top surface to the bottom surface of the body of the mounting frame; and
a panel disposed in the mounting frame, the panel having a body having a top surface and a bottom surface, the top surface of the body of the panel oriented at acute angle relative to the top surface of the body of the mounting frame.

13. The processing chamber of claim 12, wherein the acute angle is five degrees.

14. The processing chamber of claim 12, wherein the panel is substantially transparent.

15. The processing chamber of claim 12, wherein the panel is made of sapphire.

16. The processing chamber of claim 12, wherein the window is substantially circular in shape.

17. The processing chamber of claim 12, wherein the mounting frame is made of one of sapphire, fused silica, or MgF₂.

18. The processing chamber of claim 12, wherein the top surface of the mounting frame is substantially parallel to the bottom surface of the mounting frame.

19. The processing chamber of claim 12, wherein the top surface of the panel is substantially parallel to the bottom surface of the panel.

20. The processing chamber of claim 12, wherein the mounting frame further has a near outer edge connecting the top surface to the bottom surface of body of the panel, the near outer edge having a first portion, a central portion disposed above the first portion, and a third portion extending above the central portion, the central portion at least partially adjoining the inner edge of the body mounting frame.
